(19) United States
(12) Patent Application Publication
(10) Pub. No.: US 2011/0108987 A1
(43) Pub. Date: May 12, 2011

(54) SEMICONDUCTOR DEVICE

(75) Inventors: Hideyuki Tomizawa, Rensselaer, NY (US); Tadayoshi Watanabe, Oita-ken (JP); Noriaki Matsunaga, Kanagawa-ken (JP)

(73) Assignee: KABUSHIKI KAISHA TOSHIBA, Tokyo (JP)

(21) Appl. No.: 12/897,941

(22) Filed: Oct. 5, 2010

(30) Foreign Application Priority Data
Oct. 5, 2009 (JP) P2009-231195

(51) Int. Cl. H01L 23/532

(52) U.S. Cl. 257/751; 257/E23.154

(57) ABSTRACT

A semiconductor device, may include a first insulating layer formed on a semiconductor substrate, a contact provided in the first insulating layer, a second dielectric layer formed on the first insulating layer, the second insulating layer having lower dielectric constant than the first dielectric layer, a wiring formed in the second insulating layer and being electrically connected to the contact, a first barrier metal formed on a bottom of the contact and on a side surface of the wiring, and a second barrier metal formed on a side surface of the bottom and on the first barrier metal.

### CROSS REFERENCE TO RELATED APPLICATION

This application is based upon and claims the benefit of priority from Japanese Patent Application No. 2009-231195, filed on Oct. 5, 2009, the entire contents of which are incorporated herein by reference.

### BACKGROUND

A conventional method for dual damascene is disclosed such as JP 2009-94469.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a cross sectional view of a semiconductor device in accordance with a first embodiment.

FIGS. 2-4 are cross sectional views showing a manufacturing process of a semiconductor device in accordance with the first embodiment.

FIG. 5 is a cross sectional view of a semiconductor device in accordance with a second embodiment.

FIGS. 6-8 are cross sectional views showing a manufacturing process of a semiconductor device in accordance with the second embodiment.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

A semiconductor device, may include a first insulating layer formed on a semiconductor substrate, a contact provided in the first insulating layer, a second dielectric layer formed on the first insulating layer, the second insulating layer having lower dielectric constant than the first dielectric layer, a wiring formed in the second insulating layer and being electrically connected to the contact, a first barrier metal formed on a bottom of the contact and on a side surface of the wiring, and a second barrier metal formed on a side surface of the bottom and on the first barrier metal.

### First Embodiment

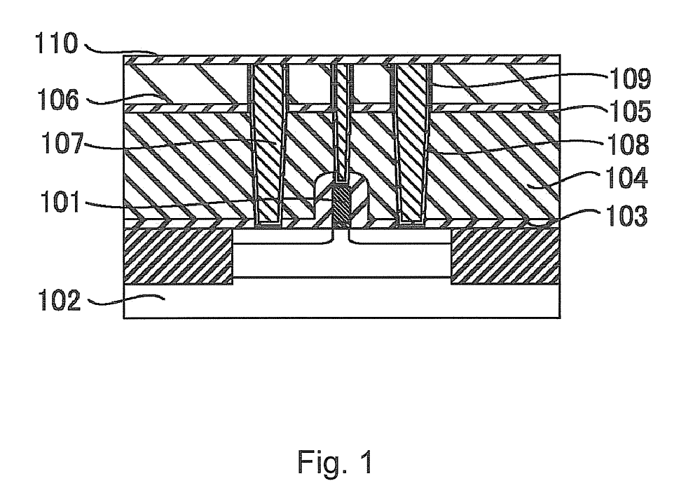

A first embodiment of the present invention will be explained hereinafter with reference to FIGS. 1-4.

As shown in FIG. 1, a liner insulating layer 103 is formed on a Si substrate 102 in which a transistor region 101 is formed. An interlayer dielectric 104 is formed on the liner insulating layer 103. A first insulating barrier layer 105, which has a function of blocking Cu diffusion, is formed on the interlayer dielectric layer 104. A low-K dielectric layer 106 is formed on the first insulating barrier layer 105. The low-K dielectric layer 106 may be a dielectric layer which has a lower dielectric constant than silicon oxide in case the interlayer dielectric 104 is silicon oxide.

A contact and a wiring 107 is formed in an opening which penetrated through the insulating layers 103-106, which are formed in the transistor region 101 and on the Si substrate 102. A first barrier metal 108 is formed around the contact and the wiring 107. The first barrier metal 108 is formed on the side surfaces of the liner dielectric layer 103, interlayer dielectric layer 104, and first insulating barrier metal layer 105. The first barrier metal 108 is also formed on the top surface of the Si substrate 102.

The second barrier metal 109 is formed between the side surface of the low-K dielectric layer 106 and the first barrier metal 108. on the side surface of the low-K dielectric layer 106, a barrier metal is two-layered lamination structure, which is the first barrier metal 108 and the second barrier metal 109. On closer side to low-K dielectric layer 106, the second barrier metal 109 is formed directly on the low-K dielectric 106. On closer side to the wiring 107, the first barrier metal 108 is formed on the wiring 107. The first barrier metal 108 may be made of a metal such as Ti. The second barrier metal 109 may be made of Ti, Ta, TaN or TiN. A second insulating barrier layer 110 is formed on the low-K dielectric layer 106 and the wiring 107. The second insulating barrier layer 110 has a function so as to block a Cu diffusion.

It is not necessary that the second barrier metal 109 is formed only between the first barrier 108 and the low-K dielectric layer 106 as shown in FIG. 1. The second barrier metal 109 is formed between the first barrier 108 and the low-K dielectric layer 106. For example, the second barrier metal 109 may be formed on an upper portion of the contact and a bottom of the wiring.

In this embodiment, the upper portion of the contact is a portion of the contact from the top of the contact to ⅚ (one sixth) of contact height.

In this embodiment, the first barrier metal 108 and the second barrier metal 109 are formed on the side surface of the low-K dielectric 106. Thus a diffusion of a material which worsens the insulation of the low-K dielectric 106 is decreased by the first barrier metal 108 and the second barrier metal 109 effectively.

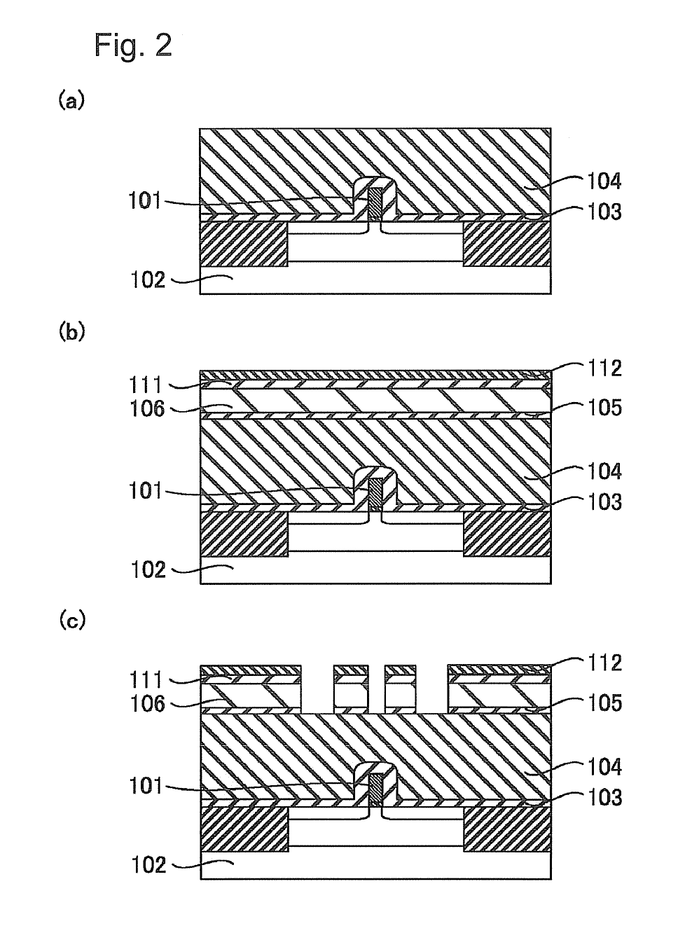

Next, a manufacturing process of the semiconductor device in accordance with this embodiment is disclosed with reference to FIGS. 2-4.

As shown in FIG. 2(a), the interlayer dielectric layer 104 and the liner insulating layer 103 are formed on the Si substrate 102. After forming the interlayer dielectric layer 104, the upper surface is planalized by CMP or the like.

As shown in FIG. 2(b), the first insulating barrier layer 105, the low-K dielectric 106, a first hard mask 111 and a second hard mask 112 are formed. The first and second hard masks have high etching selectivity to each other. For example, the first hard mask 111 is a silicon oxide and the second hard mask is a silicon nitride.

As shown in FIG. 2(c), patterning for forming a opening for wiring trench and contact hole is provided. The pattering is provided by a photo resist and lithography and the like. The first and second hard mask 111 and 112 is etched with patterned resist as a mask. And the wiring trench is formed. The wiring trench is formed in the first insulating barrier layer 105, the low-K dielectric 106 and the first and second hard mask 111 and 112.

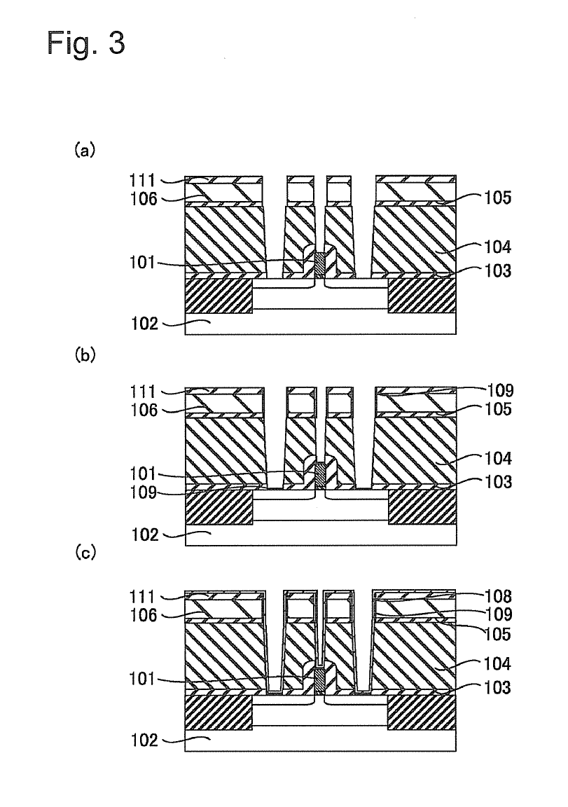

As shown in FIG. 3(a), a contact hole is formed below the wiring trench and in the liner insulating layer 103 and interlayer dielectric 104 and the first insulating barrier layer 105 by RIE and lithography or the like. So, a dual damascene structure which has the wiring trench and the contact hole thereunder is formed.

Next, a barrier metal forming process is provided. in this manufacturing process, the barrier metal is formed by forming the second barrier metal 109 by PVD and, after that, forming the first barrier metal 108 on the second barrier metal 109 by CVD.

As shown in FIG. 3(b), the second barrier metal 109 is formed on a side surface of the wiring trench and bottom of the contact hole by PVD. The wiring trench is formed in the first insulating barrier layer 105 and the low-K dielectric 106, and the contact hole is formed in the liner insulating layer 103 and the interlayer dielectric layer 104.

After forming the second barrier metal 109, the second barrier metal 109 is formed on the Si substrate 102 and a side surface of the low-K dielectric 106 and the first insulating barrier layer 105, since the aspect ratio of the contact hole is high and the metal is rarely formed on a side surface of the contact hole in a deep portion. In this process, the second barrier metal 109 may be formed on a side surface of the contact hole, which is a side surface of the interlayer dielectric 104 and the liner insulating layer 103.

By forming the second barrier metal 109, the low-K dielectric is hardly exposed to gases used during CVD. The thickness of the second barrier metal 109 is about 1-2 nm. So, the reduction of the wiring volume is suppressed.

Furthermore, the second barrier metal 109 is also formed on the Si substrate 102. So the diffusion from the contact to the Si substrate 102 is also reduced.

Later that, as shown in FIG. 3(c), the first barrier metal 108 is formed on an exposed surface of the Si substrate 102, the insulating layers 103-111, and the second barrier metal 109 by CVD. The barrier metal 108 is formed in conformal, since the barrier metal 108 is formed by CVD.

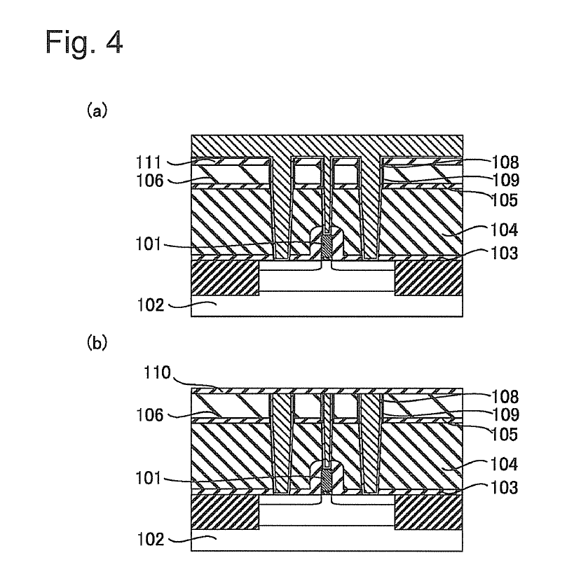

As shown in FIG. 4(a), the seed Cu is formed by sputtering and Cu is plated thereon by dual damascene method. Later that, the upper surface is planalized by CMP so as to expose the low-K dielectric layer 106.

As shown in FIG. 4(b), the second insulating barrier metal 110 is formed on the low-K dielectric layer 106.

### Second Embodiment

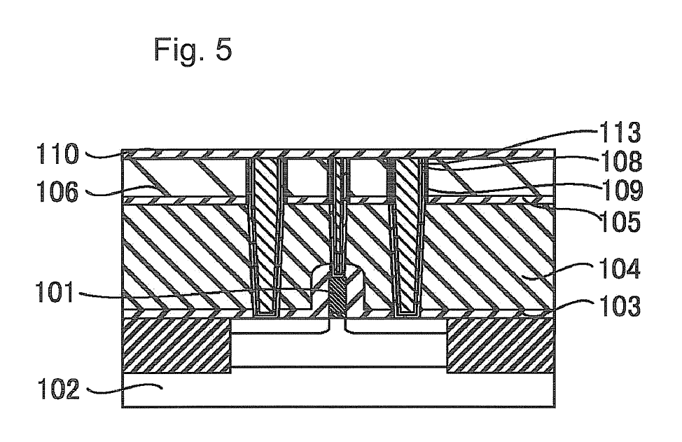

A second embodiment of the present invention will be explained hereinafter with reference to FIGS. 5-8.

In this second embodiment, a liner member 113 is formed between the first barrier metal 108 and the wiring 107.

The liner member 113 is a conductive material. The liner member 113 is formed in the wiring trench and the contact hole confomally. The liner member 113 may be Ti, Ta, TiN, TaN, Ru or the like.

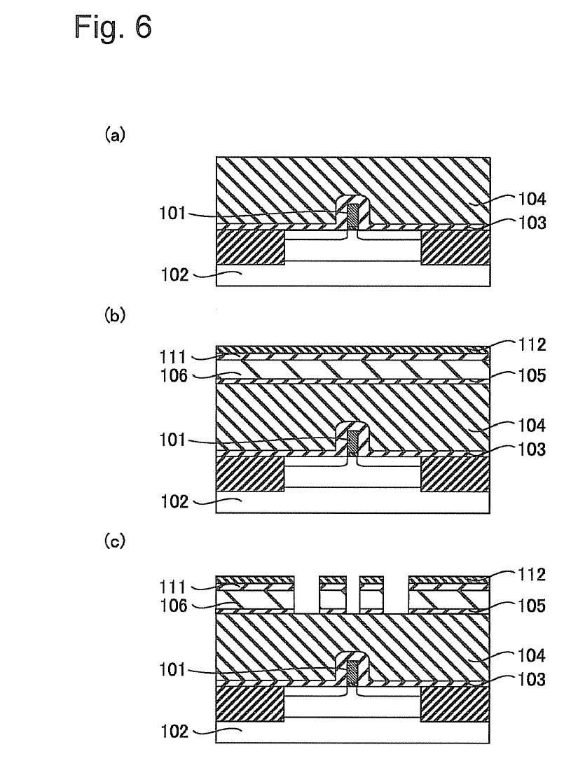

The manufacturing process is explained with reference to FIGS. 6-8.

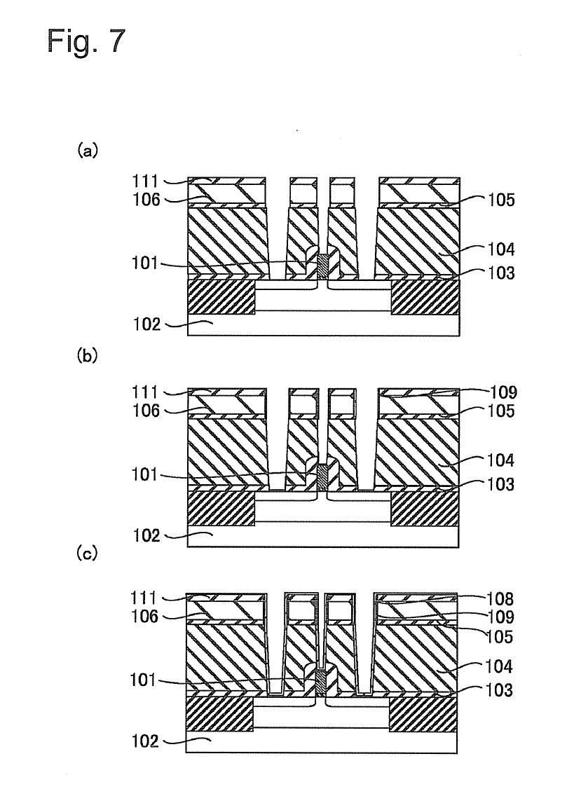

The process as shown in FIG. 6(a)-FIG. 7(c) is the same as the process shown in FIG. 2(a)-FIG. 3(c).

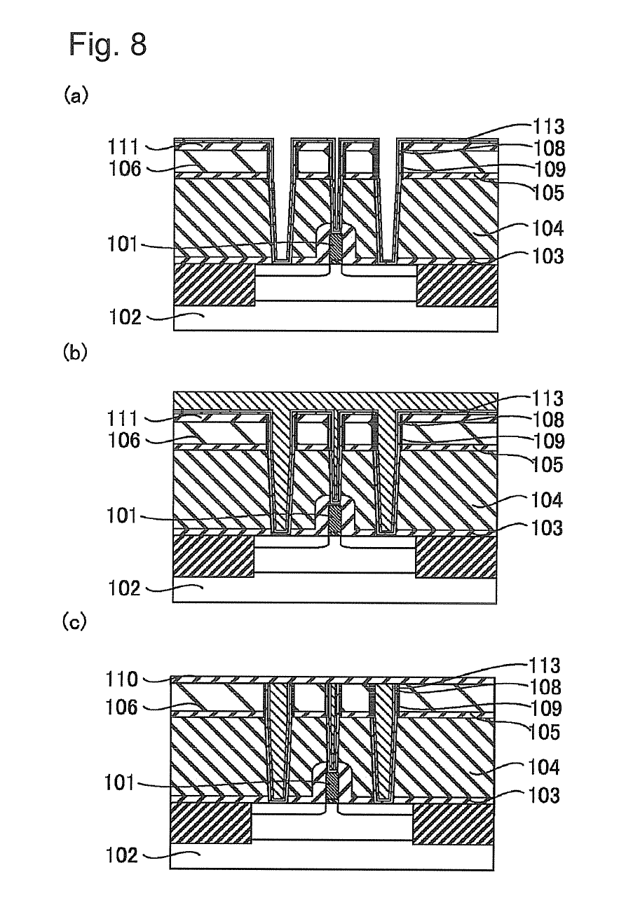

As shown in FIG. 8(a), a liner member 113 is formed on exposed surface of the second barrier metal 108. The liner member 113 is formed by PVD, CVD or the like.

As shown in FIG. 8(b), a Cu seed and plating is performed.

As shown in FIG. 8(c), the second insulating barrier layer 110 is formed after the top surface of Cu wiring is planalized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first insulating layer formed on a semiconductor substrate;
a contact provided in the first insulating layer;
a second dielectric layer formed on the first insulating layer, the second insulating layer having lower dielectric constant than the first dielectric layer; and
a wiring formed in the second insulating layer and being electrically connected to the contact;
a first barrier metal formed on a bottom of the contact and on a side surface of the wiring; and
a second barrier metal formed on a side surface of the bottom and on the first barrier metal.

2. The semiconductor device of claim 1, wherein the first barrier metal is formed on a side surface of an upper portion of the contact.

3. The semiconductor device of claim 1, wherein the first barrier metal is formed by PVD, and the second barrier metal is formed by CVD.

4. The semiconductor device of claim 1, wherein a liner member is formed between the wiring and the first barrier metal, and between the contact and the first barrier metal.

5. The semiconductor device of claim 1, wherein the first barrier metal is made of Ti, and the second barrier metal is made of Ti, Ta, TaN or TiN.
